(19) United States
(12) Patent Application Publication
(10) Pub. No.: US 2007/0077707 A1
(43) Pub. Date: Apr. 5, 2007

(54) Non volatile memory device and method of manufacturing the same

(75) Inventor: Jin-Hyo Jung, Bucheon-city (KR)

Correspondence Address: Jun-Hyo Jung, Hanra Maeul 102-902, Jung-dong, Wonmi-ku, Bucheon-city, Kyungki-do, KR

(73) Assignee: DongbuAnam Semiconductor Inc., Kangnam-ku (KR)

(21) Appl. No.: 11/319,700

(22) Filed: Dec. 29, 2005

(30) Foreign Application Priority Data
Oct. 4, 2005 (KR) 10-2005-0092923

(51) Int. Cl. H01L 21/336

(52) U.S. Cl. 438/257

(57) ABSTRACT

The present invention provides a non-volatile memory device and a method of manufacturing the same. The non-volatile memory device includes: a semiconductor substrate including an active region defined by an isolation layer, having a first conductivity type; a gate formed on the substrate; a first threshold voltage adjusting layer formed on a surface of an active region below the gate, having a second conductivity type; a second threshold voltage adjusting layer formed on a surface of an edge region of the isolation layer, having the first conductivity type; and an insulation layer formed between the gate and the substrate.

### CROSS-REFERENCE TO RELATED APPLICATION

This application claims priority to and the benefit of Korean Patent Application No. 10-2005-0092923 filed in the Korean Intellectual Property Office on Oct. 4, 2005, the entire contents of which are incorporated herein by reference.

### BACKGROUND OF THE INVENTION

(a) Field of the Invention

The present invention relates to a method of manufacturing a semiconductor device. More particularly, the present invention relates to a SONOS type non-volatile memory device and a method of manufacturing the same.

(b) Description of the Related Art

Generally, since a non-volatile memory device has several merits, such as small cell size, fast erasing and programming operation, and long-time capacity of data storage, a non-volatile memory device is frequently used as a signaling transistor in a PDA (personal digital assistance), a digital camera, a PCS (personal communication system), and a smart card, or as a memory device substituting a DRAM (dynamic random access memory).

Such non-volatile memory devices are classified into a floating gate based memory and an MIS (Metal Insulator Semiconductor) based memory.

A floating gate based memory device realizes its memory characteristic using a potential well. On the other hand, an MIS based memory device having double or triple dielectric layers realizes its memory characteristic using a trap that exists in each interface between dielectric bulk, between dielectric layers, and between a dielectric layer and a semiconductor. Therefore, an MIS based memory device is more applicable to a low voltage and high speed than a floating gate based memory device.

As a typical MIS based memory device, there is a MONOS (Metal Oxide Nitride Oxide Silicon) or SONOS (Silicon Oxide Nitride Oxide Silicon) type device which are mainly used as an EEPROM (Electrically Erasable Programmable Read Only Memory).

When a programming operation in a MONOS or a SONOS non-volatile memory device is performed, a threshold voltage is increased by trapping electrons within a trap site at a nitride layer through an FN (Fowler-Nordheim) tunneling or direct tunneling. Similarly, in the case of an erasing operation therein, a threshold voltage is decreased by releasing electrons out to a substrate through an FN (Fowler-Nordheim) tunneling, direct tunneling, or trap-assisted tunneling.

Referring to FIG. 1 and FIG. 2, a conventional SONOS type non-volatile memory device will be described.

An isolation layer 112 is formed on a P-type semiconductor substrate 110, and then an active region 114 is defined by the isolation layer 112. Subsequently, a gate 130 including a polysilicon layer is formed on an entire surface of the substrate 110 including the active region 114. The active region 114 below the gate 130 performs a function of a channel region, and a threshold voltage adjusting layer 116 is formed on the surface of the active region below the gate. In order to lower concentration of the substrate 110 in the active region below the gate, the threshold voltage adjusting layer 116 includes impurities having an opposite conductivity type with respect to that of the substrate 110, namely N-type impurities.

Accordingly, since a SONOS transistor formed on the channel region may have low threshold voltage, a memory device can be operated under low voltage of about 2.5V. Here, P, As, Sb may be used as N-type impurities.

In addition, an insulation layer 120 is formed between the gate 130 and the substrate 110, and then N-type source and drain regions 118a and 118b are formed in the active region 114 at both sides of the gate 130. Here, the insulation layer 120 is composed of an ONO structure in which a first oxide layer 122, a nitride layer 124, and a second oxide layer 126 are sequentially accumulated. The first oxide layer 122 performs a function of a tunnel oxide, and the second oxide layer 126 performs a function of a blocking oxide layer, and the nitride layer 124 performs a function of a charge storage layer.

The isolation layer 112 in a SONOS type non-volatile memory device is formed by a shallow trench isolation (STI) process.

However, the isolation layer 112 formed by the STI process has round upper edges in FIG.3 in the region A in FIG. 2 due to a typical characteristic of the STI process. Consequently, the first oxide layer 122 composing the insulation layer 120 may be formed in the round edges of the isolation layer twice or more as thick as in the other portion of the isolation layer.

Therefore, as shown in FIG. 4, since an additional parasitic SONOS transistor is created in the surface of the upper edge region A of the isolation layer 112, parasitic SONOS transistors (T_{P1}, T_{P2}) are connected in parallel to a SONOS transistor (T_{M})

Compared to the SONOS transistor (T_{M}), the parasitic SONOS transistors (T_{P1}, T_{P2}) may have a nearly constant threshold voltage regardless of program and erase operations because the program and erase operations are not properly performed in the parasitic SONOS transistors (T_{P1}, T_{P2}).

In the case of the erase operation, while the SONOS transistor (T_{M}) may have a significantly low threshold voltage because the erase operation in the SONOS transistor (T_{M}) is properly performed, the parasitic SONOS transistors (T_{P1}, T_{P2}) may maintain a high threshold voltage because the erase operation in the parasitic SONOS transistors (T_{P1}, T_{P2}) is not properly performed. Therefore, as shown in FIG. 5, the SONOS transistor (T_{M}) can perform a function of a main current because it is turned on before the parasitic SONOS transistors (T_{P1}, T_{P2}).

Consequently, the hump phenomenon may not occur during the erase operation because parasitic current caused by the parasitic SONOS transistors (T_{P1}, T_{P2}) is negligibly small.

However, in the case of the program operation, while the SONOS transistor (T_{M}) may have a significantly high threshold voltage because the program operation in the SONOS transistor (T_{M}) is properly performed, the parasitic SONOS transistors (T_{P1}, T_{P2}) may maintain a high threshold voltage because the program operation in the parasitic SONOS transistors (T_{P1}, T_{P2}) is not properly performed.

Therefore, as shown in FIG. 6, the parasitic SONOS transistors (T_{P1}, T_{P2}) can perform a function of a main current because they are turned on before the SONOS transistor (T_{M}).

Consequently, the hump phenomenon, as shown in area B of FIG. 6, may be severely created during the program operation because parasitic current caused by the parasitic SONOS transistors (T_{P1}, T_{P2}) is not negligible and the SONOS transistor (T_{M}) is turned on after the parasitic SONOS transistors (T_{P1}, T_{P2}) is turned on.

Such a hump phenomenon may increase an occurrence rate of error for an interpretation process in the program operation.

In addition, since leakage current may be increased by the parasitic SONOS transistors (T_{P1}, T_{P2}) in the SONOS type non-volatile memory device, a soft-fail rate for the SONOS type non-volatile memory device can be increased.

Therefore, characteristics and reliability of the SONOS type non-volatile memory device may be deteriorated.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a non-volatile memory device and a method of manufacturing the same having advantages of preventing hump phenomenon and leakage current caused by parasitic SONOS transistors.

An exemplary non-volatile memory device according to an embodiment of the present invention includes: a semiconductor substrate including an active region defined by an isolation layer, having a first conductivity type; a gate formed on the substrate; a first threshold voltage adjusting layer formed on a surface of an active region below the gate, having a second conductivity type; a second threshold voltage adjusting layer formed on a surface of an edge region of the isolation layer, having the first conductivity type; and an insulation layer formed between the gate and the substrate.

An exemplary method of manufacturing a non-volatile memory device according to an embodiment of the present invention includes: forming a semiconductor substrate including an active region defined by an isolation layer, the substrate having a first conductivity type; forming a photoresist pattern on the substrate; forming a first threshold voltage adjusting layer in the active region by firstly ion-implanting impurities having a second conductivity type into the substrate using the photoresist pattern as an ion implantation mask; forming a second threshold voltage adjusting layer in an edge region of the isolation layer by secondly ion-implanting impurities having a first conductivity type into the substrate using the photoresist pattern as an ion implantation mask; forming an insulation layer on the substrate; and forming a gate on the insulation layer.

The insulation layer may be composed of a structure in which a first oxide layer, a nitride layer, and a second oxide layer are sequentially accumulated.

In addition, the second ion implantation may be performed in a tilted direction to the substrate, preferably at a tilt angle of 5 to 80°, and it may be performed four times in panning as much as 90°.

### BRIEF DESCRIPTION OF THE DRAWINGS

FIG. 1 is a top plan view showing a layout of a conventional non-volatile memory device.

FIG. 2 is a cross-sectional view showing a conventional non-volatile memory device.

FIG. 3 is a drawing showing an edge of an isolation layer of a conventional non-volatile memory device.

FIG. 4 is a circuit diagram showing parasitic transistors created in a conventional non-volatile memory device.

FIG. 5 is a graph showing drain current (Id) characteristics with respect to gate voltage (Vg) during an erase operation for a conventional non-volatile memory device.

FIG. 6 is a graph showing drain current (Id) characteristics with respect to gate voltage (Vg) during a program operation for a conventional non-volatile memory device.

FIG. 7A to FIG. 7E are cross-sectional views showing sequential stages of a method for manufacturing a non-volatile memory device according to an exemplary embodiment of the present invention.

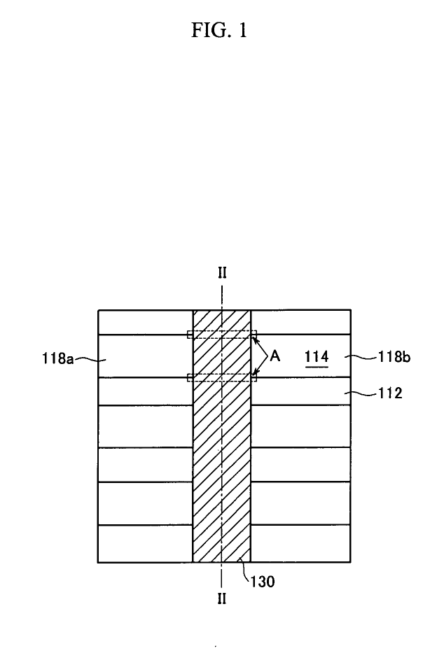

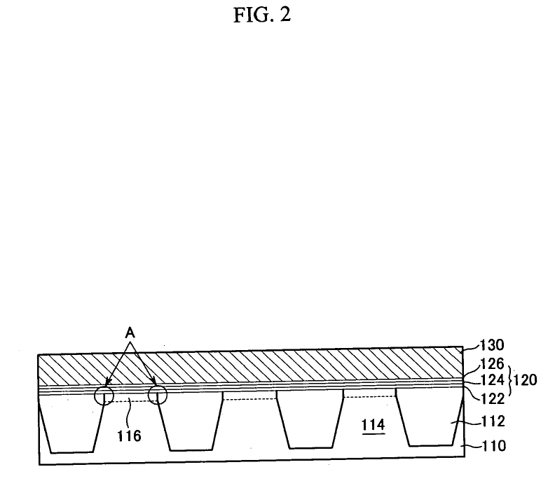

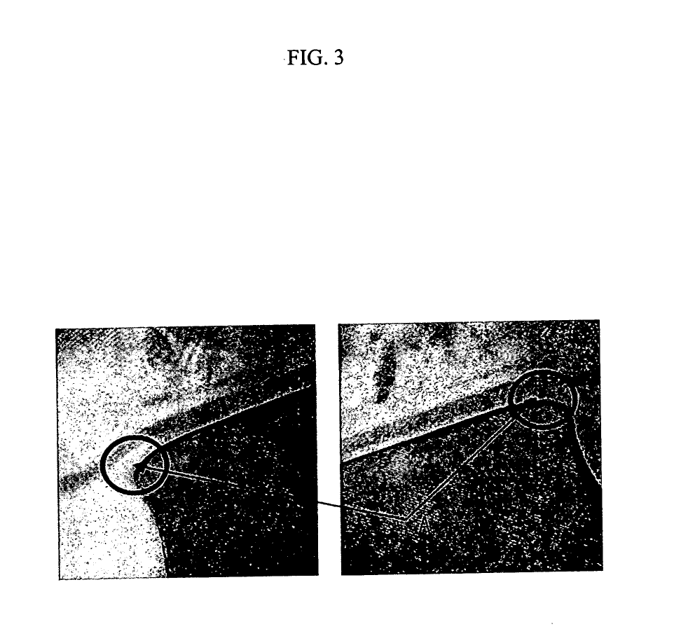

### DETAILED DESCRIPTION OF THE EMBODIMENT

With reference to the accompanying drawings, the present invention will be described in order for those skilled in the art to be able to implement the invention. As those skilled in the art would realize, the described embodiment may be modified in various different ways, all without departing from the spirit or scope of the present invention.

To clarify multiple layers and regions, the thicknesses of the layers are enlarged in the drawings. Like reference numerals designate like elements throughout the specification. When it is said that any part, such as a layer, film, area, or plate is positioned on another part, it means the part is directly on the other part or above the other part with at least one intermediate part. On the other hand, if any part is said to be positioned directly on another part it means that there is no intermediate part between the two parts.

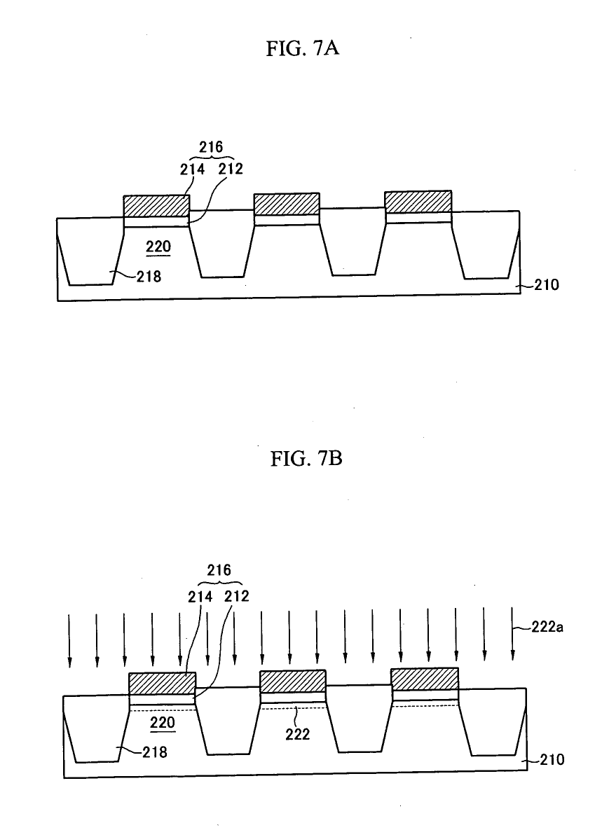

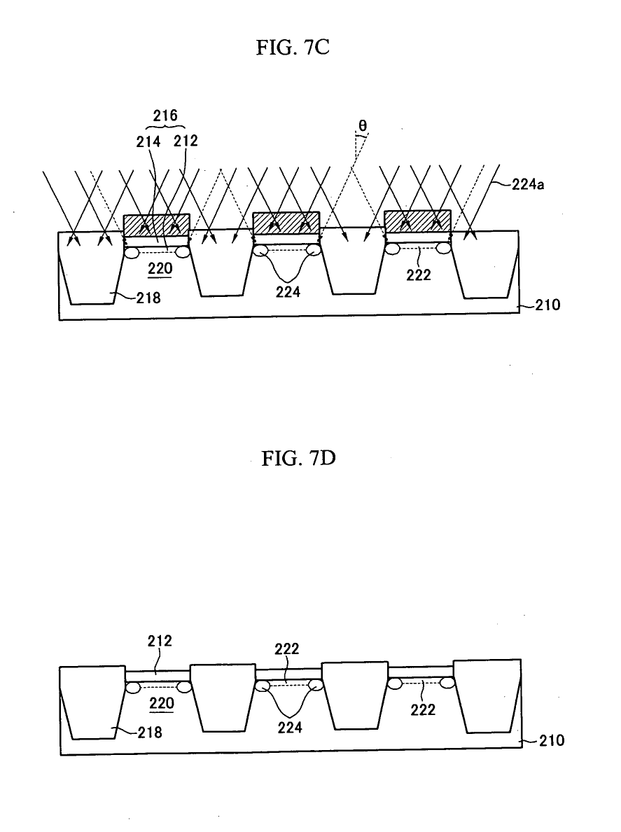

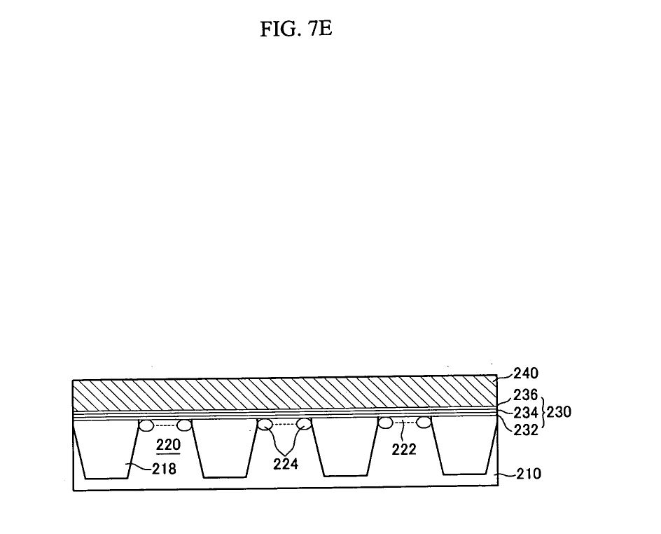

Referring to FIG. 7E, a SONOS type non-volatile memory device according to an exemplary embodiment of the present invention will be described in detail. According to an exemplary embodiment of the present invention, a SONOS type non-volatile memory device is formed as an NMOS type.

As shown in FIG. 7E, an isolation layer 218 is formed on a P-type semiconductor substrate 210 including a P-well (not shown), and then an active region 220 is defined by forming the isolation layer 218.

Subsequently, a gate 240 including a polysilicon layer is formed on an entire surface of the substrate 210 including the active region 220. The active region 220 below the gate 240 performs a function of a channel region, and a first threshold voltage adjusting layer 222 is formed on the surface of the active region below the gate.

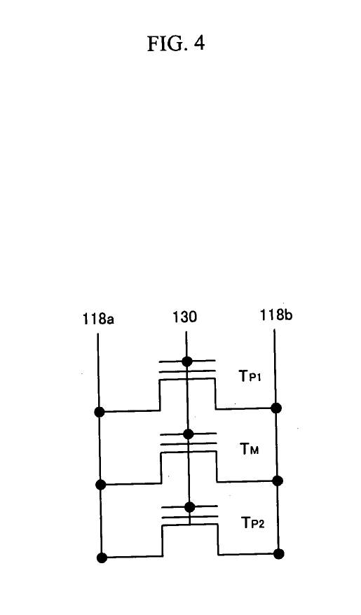

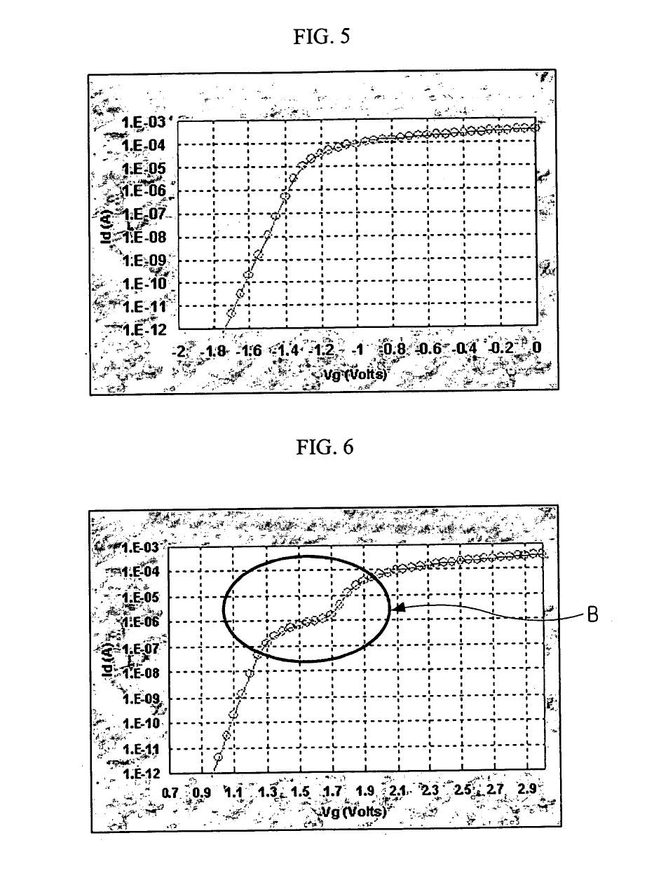

Since the first threshold voltage adjusting layer 222 is composed of impurities having the opposite conductivity type with respect to the substrate 210, namely N-type impurities, the SONOS transistor (T_{M}) (refer to FIG. 4) formed on the channel region may have a low threshold voltage. Accordingly, a flash memory device may be operated under a low voltage of about 2.5V. Here, P, As, Sb may be used as the N-type impurities.

In addition, a second threshold voltage adjusting layer 224 is formed on the surface of the edge region (A) of the isolation layer 218. The second threshold voltage adjusting layer 224 is composed of impurities having the same conductivity type as the substrate 210, namely P-type impurities, such that the parasitic SONOS transistors (T_{P1}, T_{P2}) (refer to FIG. 4) formed on the surface of the edge region (A) of the isolation layer 218 may have a higher threshold voltage than the SONOS transistor (T_{M}) (refer to FIG. 4). At this time, B, BF₂, or in may be used for the P-type impurities.

On the other hand, if the SONOS type non-volatile memory device has a PMOS type, the second threshold voltage adjusting layer 224 is composed of the N-type impurities. At this time, Ph, As, or Sb may be used for the N-type impurities.

In addition, an insulation layer 230 is formed between the gate 240 and the substrate 210, and then N-type source and drain regions (not shown) are formed in the active region 218 at both sides of the gate 240.

Here, the insulation layer 230 is composed of an ONO structure in which a first oxide layer 232, a nitride layer 234, and a second oxide layer 236 are sequentially accumulated. The first oxide layer 122 performs a function of a tunnel oxide, and the second oxide layer 126 performs a function of a blocking oxide layer, and the nitride layer 124 performs a function of a charge storage layer.

According to an exemplary embodiment of the present invention, the parasitic SONOS transistors (T_{P1}, T_{P2}) formed on the surface of the edge region (A) of the isolation layer 218 may have a higher threshold voltage than the SONOS transistor (T_{M}) formed in the channel region.

Consequently, when the program operation for the SONOS type non-volatile memory device is performed, the hump phenomenon and an increase of leakage current, which are created during the program operation for the SONOS type non-volatile memory device, can be prevented because the main SONOS transistor (T_{M}) performs a function of a main current

Subsequently, a method of forming a SONOS type non-volatile memory device will be described in detail with reference to FIG. 7A to FIG. 7E.

Referring to FIG. 7A, a pad oxide layer 212 and pad nitride layer 214 are sequentially deposited on a P-type semiconductor substrate 210, and then a mask pattern 216 exposing a device isolation region of the substrate 210 is formed by patterning the pad oxide layer 212 and the pad nitride layer 214 through a photolithography process and etching process.

Subsequently, a trench is formed by etching portions of the substrate 210 exposed by the mask pattern 216, and then an oxide layer is deposited on the entire surface of the substrate 210 so as to fill the trench. An isolation layer 218 is formed by removing the oxide layer by a chemical mechanical polishing (CMP) process to a degree that the surface of the mask pattern 216 is exposed.

Referring to FIG. 7B, a photoresist pattern (not shown) for a threshold voltage adjusting layer is formed on the substrate 210 by a photolithography process, and a first threshold voltage adjusting layer 222 is formed on the surface of the channel region in the active region 220 by a first ion implantation for impurities having the opposite conductivity type with respect to the substrate 210, namely N-type impurities 222a. The first ion implantation is performed by using the photoresist pattern for the threshold voltage adjusting layer as a mask and it is performed in the vertical direction to the substrate 210. At this time, P, As, Sb are used for the N-type impurities 222a during the first ion implantation.

Referring to FIG. 7C, a second threshold voltage adjusting layer 224 is formed on the surface of the edge region of the isolation layer 218 by a second ion implantation for impurities having the same conductivity type as the substrate 210, namely P-type impurities 224a. The second ion implantation is performed by using the photoresist pattern for the threshold voltage adjusting layer as a mask and it is performed in a tilted direction to the substrate 210. At this time, the second ion implantation is performed with a tilt angle of 5 to 80°, and it is performed four times in panning as much as 90°. B, BF₂, In are used for the P-type impurities 224a in the second ion implantation.

On the other hand, if the SONOS type non-volatile memory device has a PMOS type, the second threshold voltage adjusting layer is composed of the N-type impurities. At this time, Ph, As, or Sb may be used for the N-type impurities.

Referring to FIG. 7D, the photoresist pattern is removed by a well-known method. Subsequently, a heat treatment process by a furnace annealing or rapid thermal annealing (RTA) is performed for activating the ion-implanted impurities, and the nitride layer 214 in the mask pattern 216 is removed.

However, the heat treatment process may be performed after removing the nitride layer 214 in the mask pattern 216.

In addition, the heat treatment process may be omitted in order to simplify the manufacturing process.

Referring to FIG. 7E, a P-well (not shown) is formed on the substrate 210, and the pad oxide layer 212 is removed. Subsequently, an insulation layer 230 is formed on the substrate 210, and a gate 240 is formed on the insulation layer 230. The insulation layer 230 is composed of an ONO structure in which a first oxide layer 232, a nitride layer 234, and a second oxide layer 236 are sequentially deposited on the substrate 210.

According to an exemplary embodiment of the present invention, a threshold voltage for the SONOS transistor may be increased by using a mask pattern for an ordinary threshold voltage adjusting layer without the process of forming an additional mask. Therefore, additional manufacturing cost for controlling the threshold voltage in the parasitic SONOS transistor is not required according to the exemplary embodiment of the present invention.

In addition, as described above, the hump phenomenon and leakage current that are caused by the parasitic SONOS transistor can be prevented, and characteristics and reliability of the non-volatile memory device may be enhanced.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A non-volatile memory device, comprising:
a semiconductor substrate including an active region defined by an isolation layer, having a first conductivity type;
a gate formed on the substrate;
a first threshold voltage adjusting layer formed on a surface of the active region below the gate, having a second conductivity type;
a second threshold voltage adjusting layer formed on a surface of an edge region of the isolation layer, having the first conductivity type; and
an insulation layer formed between the gate and the substrate.

2. The non-volatile memory device of claim 1, wherein the insulation layer is composed of a structure in which a first oxide layer, a nitride layer, and a second oxide layer are sequentially accumulated.

3. The non-volatile memory device of claim 1, wherein, when the first conductivity type is P-type, the second conductivity type is N-type, and when the first conductivity type is N-type, the second conductivity type is P-type.

4. A method of manufacturing a non-volatile memory device, comprising:
forming a semiconductor substrate including an active region defined by an isolation layer, the substrate having a first conductivity type;
forming a photoresist pattern on the substrate;
forming a first threshold voltage adjusting layer in the active region by firstly ion-implanting impurities having a second conductivity type into the substrate using the photoresist pattern as an ion implantation mask;
forming a second threshold voltage adjusting layer in an edge region of the isolation layer by secondly ion-implanting impurities having a first conductivity type into the substrate using the photoresist pattern as an ion implantation mask;
forming an insulation layer on the substrate; and
forming a gate on the insulation layer.

5. The method of claim 4, wherein the insulation layer is composed of a structure in which a first oxide layer, a nitride layer, and a second oxide layer are sequentially accumulated.

6. The method of claim 4, wherein the second ion implantation is performed in a tilted direction to the substrate.

7. The method of claim 4, wherein the second ion implantation is performed with a tilt angle of 5 to 80°.

8. The method of claim 6, wherein the second ion implantation is performed four times in panning as much as 90°.

9. The method of claim 7, wherein the second ion implantation is performed four times in panning as much as 90°.

10. The method of claim 4, wherein, when the first conductivity type is P-type, the second conductivity type is N-type, and when the first conductivity type is N-type, the second conductivity type is P-type.

11. The method of claim 10, wherein, when the first conductivity type is P-type, one among B, BF₂, and In is used for the impurities for forming the second threshold voltage adjusting layer.

12. The method of claim 10, wherein, when the first conductivity type is N-type, one among P, As, and Sb is used for the impurities for forming the second threshold voltage adjusting layer.
